(19) United States
(12) Patent Application Publication
(10) Pub. No.: US 2024/0038604 A1
(43) Pub. Date: Feb. 1, 2024

(54) METHODS OF MANUFACTURING SEMICONDUCTOR DEVICES AND CORRESPONDING SEMICONDUCTOR PRODUCTS

(71) Applicant: STMicroelectronics S.r.l., Agrate Brianza (MB) (IT)

(72) Inventors: Luca CECCHETTO, Missaglia (IT); Alessandra Piera MERLINI, Albiate (MB) (IT); Gabriella ADDESA, Montevecchia (IT)

(73) Assignee: STMicroelectronics S.r.l., Agrate Brianza (MB) (IT)

(21) Appl. No.: 18/224,805

(22) Filed: Jul. 21, 2023

(30) Foreign Application Priority Data
Jul. 28, 2022 (IT) 102022000016002

(51) Int. Cl. H01L 21/66; H01L 23/522; H01L 21/768

(52) U.S. Cl. CPC H01L 22/32; H01L 23/5226; H01L 21/76802; H01L 21/76877

(57) ABSTRACT

A semiconductor chip has a top metal layer with a passivation over an outer surface and including a first region and a second region. The passivation is fully removed from the first region and a contact layer for electrical wafer sorting probes is formed over the first region having the passivation fully removed therefrom. The passivation is initially only partly removed from the second region to protect the top met layer. Later, a remaining portion of the passivation is fully removed at the second region. Then, top metal layer at the second region provides a growth region for growing electrically conductive material over the second region.

### PRIORITY CLAIM

This application claims the priority benefit of Italian Application for Patent No. 102022000016002, filed on Jul. 28, 2022, the content of which is hereby incorporated by reference in its entirety to the maximum extent allowable by law.

### TECHNICAL FIELD

The description relates to manufacturing semiconductor devices.

The description may apply, by way of example, to technologies using top metal (e.g., copper) layers that can be used in a variety of products such as audio amplifiers, power management integrated circuits (PMICs), and hard disk drive (HDD) controllers.

### BACKGROUND

Various technologies used for, e.g., Quad-Flat No-leads package integration involve metal (copper) growth occurring on similar pad surfaces. Direct Copper Interconnect (DCI) or Laser Direct Structuring (LDS) are exemplary of such technologies.

It is noted that such growth cannot occur satisfactorily over aluminum capping (AlCap) or nickel-palladium (NiPd) layers as used for Electrical Wafer Sorting (EWS).

On the one hand, laser beam energy used in DCI or LDS has difficulties to ablate AlCap or NiPd layers. Otherwise, when copper pads are used for EWS having no AlCap or NiPd finishing (for instance bare Cu or Cu covered by a thin passivation layer), contamination/corrosion issues arise, which militate against EWS testability and may give rise to pad reliability issues.

There is a need in the art to address the issues discussed in the foregoing.

### SUMMARY

One or more embodiments relate to a method.

One or more embodiments also relate to corresponding semiconductor products both as an intermediate product and as a resulting semiconductor device.

Solutions as described herein are based on the general concept of providing a die bonding pad structure comprising two zones or areas dedicated to Electrical Wafer Sorting (EWS) and metal growth as used in Direct Copper Interconnect (DCI)/Laser Direct Structuring (LDS), respectively.

Solutions as described herein involve only minor front end (FE) design and integration changes with no appreciable changes in EWS and metal growth.

Solutions as described herein may include a contact pad comprising first and second areas over a metal (e.g., copper) pad.

In solutions as described herein: in the first area, dedicated to Electrical Wafer Sorting (EWS), all passivation layers are removed to expose the underlying metal (copper) pad and to form an, e.g., AlCap finishing thereon; and in the second area, dedicated to metal growth, one or more passivation layers are opened, possibly maintaining over the metal pad at least one protective layer that is finally removed during assembly of a semiconductor device.

Solutions as described herein are advantageous insofar as they do not compromise EWS flow, while effectively countering undesired Cu contamination.

Solutions as described herein do not involve dedicated probe cards. Dedicated pad finishing can be provided to facilitate secure EWS and assembly.

Solutions as described herein thus provide a feasible solution for DCI without associated risk for EWS.

In fact, solutions as described herein may involve a conventional flow until an, e.g., AlCap mask is provided, with, e.g., just one additional mask for DCI passivation opening.

A dedicated passivation etch step can stop on a protective (e.g., SiN) layer with no impact on AlCap: a DCI laser can then remove passivation fully from the DCI area. The presence of etching in the DCI area facilitates the identification of pad areas reducing mis-alignment risk. Passivation layer thickness may remain compatible with DCI flow.

### BRIEF DESCRIPTION OF THE DRAWINGS

One or more embodiments will now be described, by way of example only, with reference to the annexed figures, wherein:

FIGS. 1A to 1G are exemplary of possible steps in implementing solutions as described herein;

FIGS. 2 to 4 are partial cross-sectional views of semiconductor products suited to be manufactured according to embodiments of the present description;

FIG. 5 is a plan view of a portion of a semiconductor product manufactured with embodiments of the present description; and

FIG. 6 is a further partial cross-sectional view of a semiconductor product suited to be manufactured according to embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured. Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description: unless the context indicates otherwise, like parts or elements are indicated in the various figures with like reference signs, and a corresponding description will not be repeated for each and every figure; and manufacturing a single device will be described, being otherwise understood that current manufacturing processes of semiconductor devices involve manufacturing concurrently plural devices that are separated into single individual devices in a final dicing/singulation step.

Various technologies have been recently introduced in the manufacture of semiconductor devices such as integrated circuits (ICs).

For instance, the designation “Damascene” process applies (by way of analogy with traditional techniques of metal inlaying) to a process where an insulating layer (e.g., silicon oxide) is patterned with trenches where a conductor is desired to be provided. A coating of copper is deposited on the insulator, and the copper in excess above the insulating layer is removed and left only in the trenches of the insulating layer to form a conductive pattern. A multilayer interconnect structure can be created with successive layers of insulator and copper.

Laser Direct Structuring (LDS)—oftentimes referred to also as Direct Copper Interconnection (DCI) technology—is a laser-based machining technique now widely used in various sectors of the industrial and consumer electronics markets, for instance for high-performance antenna integration, where an antenna design can be directly formed onto a molded plastic part.

In an exemplary process, the molded parts can be produced with commercially available insulating resins that include additives suitable for the LDS/DCI process; a broad range of resins such as polymer resins like PC, PC/ABS, ABS, LCP are currently available for that purpose.

A laser beam can be used to transfer (“structure”) a desired electrically-conductive pattern onto a plastic molding that may then be subjected to metallization to finalize a desired conductive pattern.

Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

For instance, a resin having metal oxide particles dispersed therein is “structured” or “activated” locally with laser beam energy according to a desired conductive pattern. The laser beam activates the metal oxide on the surface. The activated metal oxide can be plated in an electroless plating bath after which electrolytic deposition may lead to the formation of electrically conductive vias and traces.

For instance, LDS/DCI technology facilitates replacing wires, clips or ribbons with lines/vias created by laser beam processing of an LDS material followed by metallization (growing metal such as copper via a plating process, for instance).

Electrical Wafer Sorting (EWS) refers to the operation of electrically testing dice on a semiconductor wafer such as a silicon wafer.

Solutions as described herein can be applied advantageously in the context of an (integrated circuit) semiconductor chip comprising a front (top) metal layer such as, for instance, a Cu Damascene top metallization 10.

These data are of course merely by way of example and non-limiting of the embodiments.

Solutions as described herein can likewise be applied in the context of DCl/LDS package solutions (for QFN packages, for instance) where metal (e.g., copper—Cu) pads are involved including bare metal (e.g., bare Cu) or metal covered by a thin passivation layer.

As known to those of skill in the art, passivation layers such as the passivation indicated by the reference 12 in the figures are intended to provide protection of a surface from the surrounding environment. Passivation layers usually include inert, corrosion-resistant dielectrics such as, by way of some possible examples, alumina (Al₂O₃), doped/undoped silicon (di)oxide (SiO₂) or silicon nitride (SiNₓ) or oxynitride (SiON), or silicon carbide (SiC).

Solutions as described herein are also intended to facilitate standard Electrical Wafer Sorting (EWS) and thus include, e.g., Al or NiPd pads.

It is noted that EWS is feasible adequately on bare Cu pads only at temperatures below and in a full EWS temperature range on Cu covered by a thin passivation layer. Retesting “at hot” may require a dedicated procedure.

In any case, undesired contamination may occur in all possible configurations (bare Cu or Cu covered by a thin passivation layer).

To summarize:
adequate DO/LDS metal growth is facilitated on a pad surface such as a Cu pad surface (an AlCap/NiPd layer militates against adequate growth);
laser sources used in DCl/LDS processes are unable to remove AlCap/NiPd layers;
standard EWS is facilitated by, e.g., Al or NiPd pads and is feasible on bare Cu pads only at temperatures less than 50° C.: it may be feasible on Cu covered by a thin passivation layer over a full EWS temperature range, with retest “at hot” with a dedicated procedure possibly required; and
contamination issues may arise with bare Cu or Cu covered by thin passivation layer as clearly revealed by contact with wafer after probing of Cu pad.

For the sake of completeness, it is also noted that Al₂O₃, SiN or similar sealing layers may allow one single EWS step at hot temperature and that larger pads with dedicated areas for each EWS probing step may allow multiple testing at hot temperature: in any case, neither of these approaches can deal adequately with contamination issues.

Solutions as exemplified herein start from a conventional metal layer 10 (e.g., a Damascene copper layer provided on top an integrated circuit semiconductor product structured as discussed previously) with the ability of: providing a (e.g., AlCap or NiPd) pad facilitating EWS probing in a first area; and forming in the passivation an opening which lands on a protective (e.g., SiN) layer in a second area.

In solutions as exemplified herein, two types of pad surfaces become available, such as, for instance: an, e.g., AlCap or NiPd finishing for probing (EWS); and Cu (e.g., Damascene with SiN) for DCI/LDS processing.

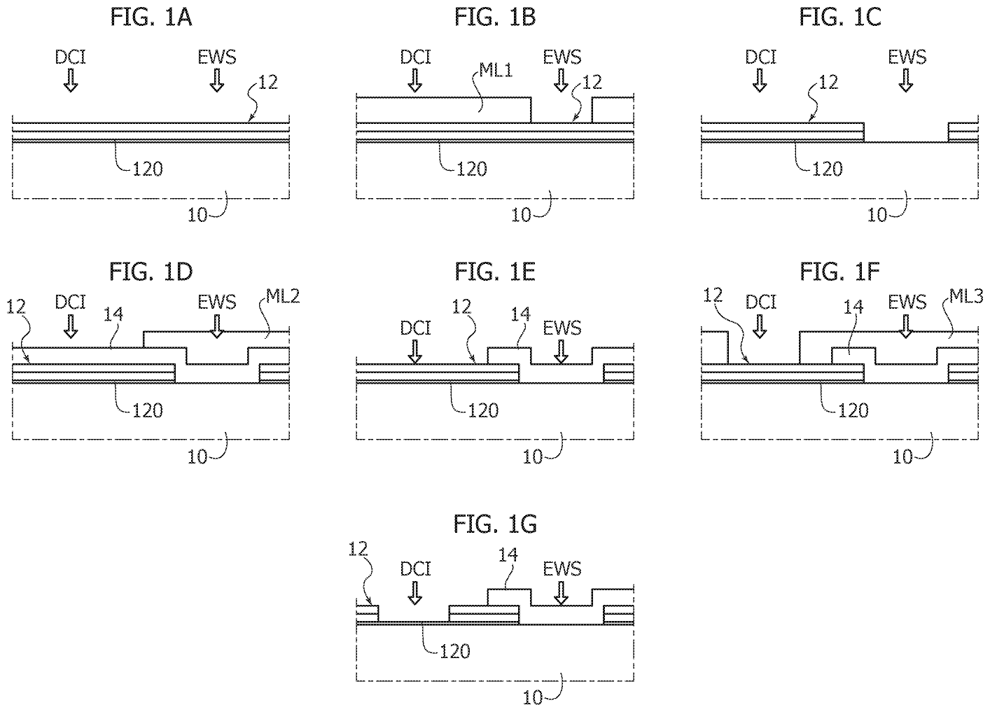

FIGS. 1A to 1G are exemplary of possible steps in implementing embodiments of the present description.

It will be appreciated that the sequence of steps of FIGS. 1A to 1G is merely exemplary insofar as: one or more steps illustrated in FIGS. 1A to 1G can be omitted, performed in a different manner (with other tools, for instance); one or more steps (e.g., providing photoresist masks) can be replaced by other steps; additional steps may be added; and one or more steps can be carried out in a sequence different from the sequence illustrated.

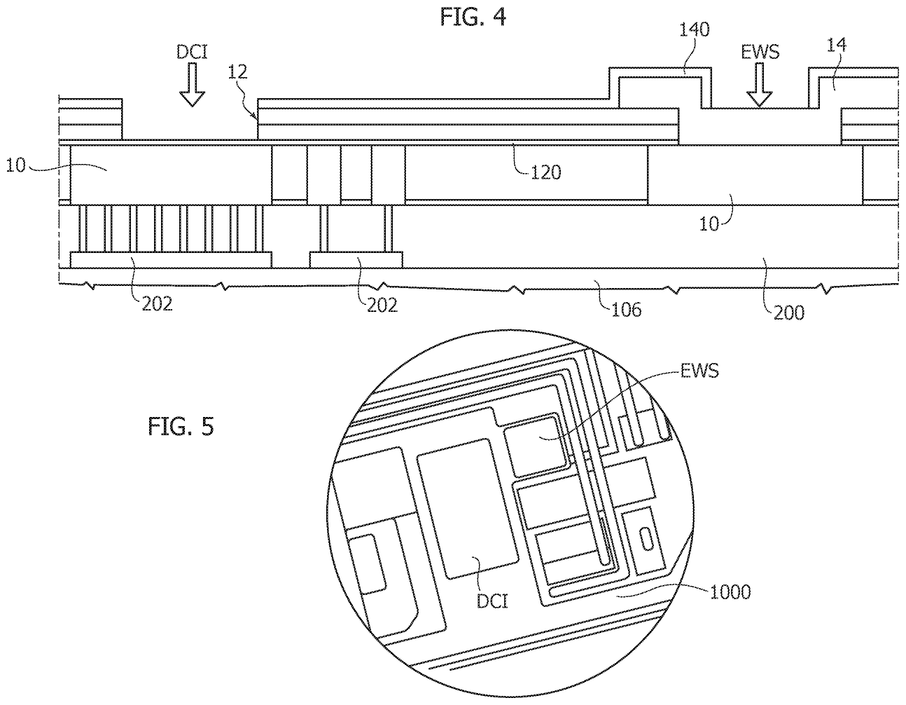

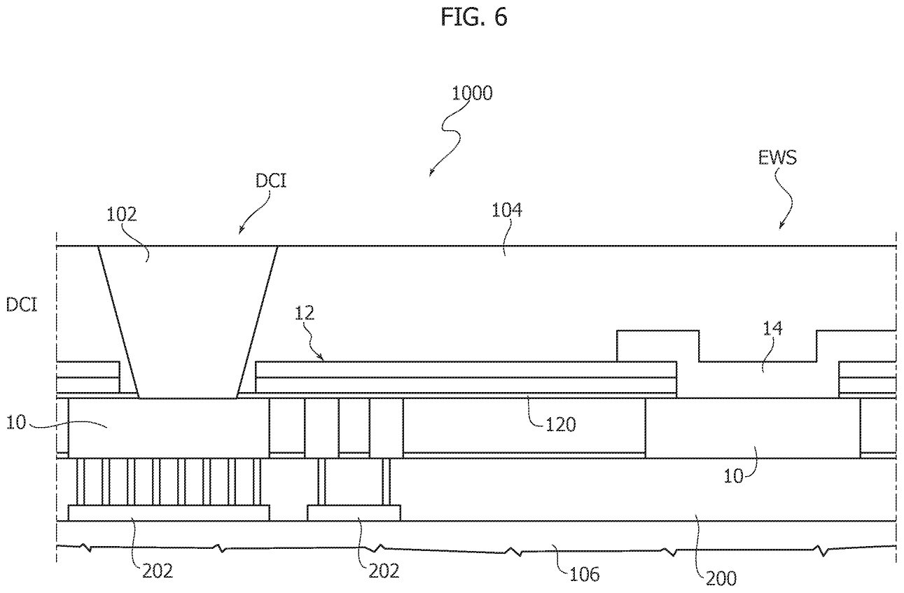

FIGS. 1A to 1G refer for simplicity and ease of understanding to processing steps performed on a metal layer 10 comprising, for instance, a Cu Damascene top metallization of an integrated circuit semiconductor product structure. How the result of these steps performed on such a layer 10 can be exploited in a semiconductor product/device is illustrated, for instance, in FIGS. 5 and 6.

Copper is referred to throughout this description as exemplary of the layer 10 insofar as copper is an advantageous choice, e.g., for reasons of cost. Copper can be used in undoped form as well as in doped form with other materials.

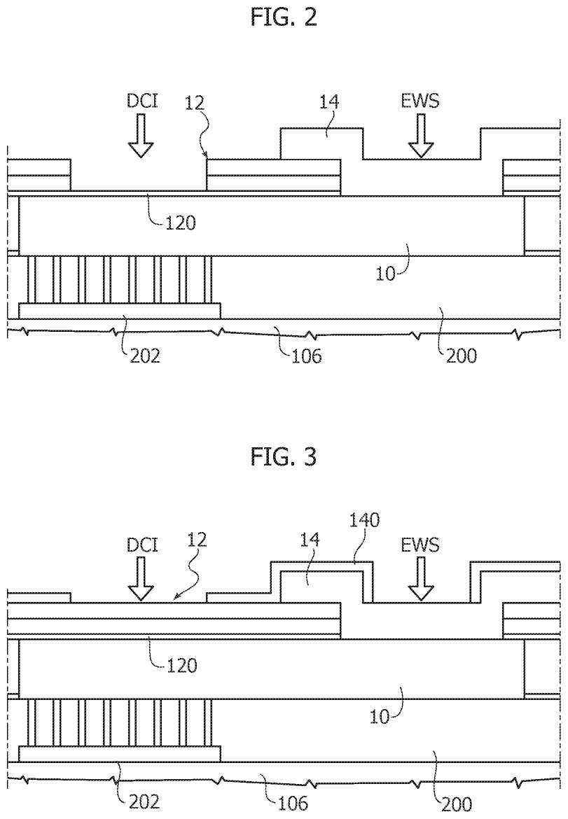

Reference 10 in FIG. 1A denotes a metal layer 10, such as, e.g., a Cu Damascene top metallization of an (otherwise conventional) underlying semiconductor chip structure. That structure (indicated as 106 in FIGS. 2 to 4, and 6) is not visible in FIGS. 1A to 1G for simplicity.

The metal layer 10 has a passivation 12 formed at a first outer (here upper or top) surface.

Examples of known materials suitable for providing such a single-layer/multi-layer passivation 12 have been discussed previously. Methods for forming such a passivation are known to those of skill in the art, which makes it unnecessary to provide a more detailed description herein.

A protective layer 120, e.g., a SiN layer (alternative materials may include doped/undoped silicon oxide, oxynitride or carbide) can be advantageously provided over the layer 10 to protect the metal in the layer 10.

The protective layer 120 may in fact be considered as included in the passivation 12: the reasons for discussing it as a distinct element will become more apparent in the following.

FIG. 1A (and the same applies also to FIGS. 1B to 1G) highlight the possible presence in the top or front surface of the metal layer 10 of: at least one first (electrically conductive) region or area, designated EWS, of the metal layer 10, the at least one first (electrically conductive) region intended to be used—in a manner known per se to those of skill in the art—within the framework of Electrical Wafer Sorting of a resulting semiconductor device (e.g., for landing EWS probes—not visible in the figures); and at least one second (electrically conductive) region or area, designated DCI, of the metal layer 10, the at least one second (electrically conductive) region intended to be used—again in a manner known per se to those of skill in the art (see the discussion provided previously)—for growing thereon electrically conductive material, for instance by acting as an electrode in electrolytic growth of conductive material such as copper) within the framework of Laser Direct Structuring (LDS)/Direct Copper Interconnect (DCI) processing.

FIG. 1B is exemplary of a first mask layer ML1 being formed onto the layer 10 (and the passivation 12) leaving the first region EWS uncovered.

The mask layer ML1 may include, in an otherwise conventional manner, photo-resist material.

FIG. 1C is exemplary of the passivation 12 being (fully, that is, including the layer 120) etched away from the first region EWS left uncovered by the mask ML1 thus exposing the metal layer 10 underneath.

Etching may be, for instance, dry and/or wet etching as otherwise conventional in the art.

FIG. 1C is exemplary of the situation after the mask ML1 has been removed (e.g., via dry and/or wet etching).

This is in contrast with processing at the region or area DCI as discussed in the following, where the layer 120 may be left in place as a protective layer of the pad 10.

FIG. 1D is exemplary of a layer 14 of material suited for use (e.g., for probing) in Electrical Wafer Sorting (EWS) being deposited—in a manner known to those of skill in the art—over the (etched out) first region EWS.

Aluminum capping material (AlCap) may be exemplary of the material 14; NiPd finishing may represent an alternative choice for the material 14.

FIG. 1D is exemplary of the layer 14 being first deposited over the whole surface (both regions EWS and DCI) and then etched away using a second mask ML2 (in an otherwise conventional manner, e.g., photo-resist mask) from the DCI area to be finally left (only) at the first area dedicated to EWS.

FIG. 1E is exemplary of the material 14 being etched away from the second region DCI left uncovered by the mask ML2. Again, etching may be, for instance, dry and/or wet etching as otherwise conventional in the art. FIG. 1E is exemplary of the situation after the mask ML2 has been removed (e.g., via dry and/or wet etching).

As those of skill in the art can appreciate, other known techniques can be used to grow the metal layer 14 in a selective way (only) over the region EWS without using a mask such as the mask ML2.

FIG. 1F is exemplary of a third mask layer ML3 being formed at the first region EWS over the material 14, the third mask layer ML3 leaving the second region DCI uncovered.

Finally, FIG. 1G is exemplary of the passivation 12 being at least partly etched away from the second region DCI left uncovered by the mask ML3. Once more, etching may be, for instance, dry and/or wet etching as otherwise conventional in the art. FIG. 1G is exemplary of the situation after the mask ML3 has been removed (e.g., via dry and/or wet etching).

Advantageously, a part of passivation (e.g., the layer 120 or more passivation layers) is not etched in order to protect the underlying metal layer 10. As discussed in the following, the layer 120 can be removed at a later stage, e.g., by laser ablation during DCI or similar processing.

The presence of etching in the DCI area otherwise facilitates the identification of pad areas reducing mis-alignment risk. Passivation layer thickness may remain compatible with DCI flow.

Solutions as presented herein provide a feasible solution for DO/LDS processing with no associated risk for Electrical Wafer Sorting (EWS).

In fact, an essentially standard flow can be adopted in up to forming the (e.g., AlCap or NiPd) finishing 14.

One additional mask (namely ML3) can then be used for “opening” the passivation 12 at the region DCI with a dedicated passivation etch step possibly suited to stop, e.g., at the layer 120 without impacting AlCap or NiPd etch.

As noted, some DCl/LDS lasers would not be able to remove a full passivation thickness. Other lasers could remove passivation fully, but pad definition would be exposed to a mis-alignment risk since a dedicated area for laser drilling (or, more generally, to connection created using laser or other etching methods) would not be well identified.

Solutions as described herein can be further applied in case of additional passivation layers 140 on top of metallization used in the area dedicated to EWS (see, for instance FIGS. 3 and 4).

It is once more recalled that one or more steps illustrated in FIGS. 1A to 1G can performed in a different manner with one or more steps (e.g., providing photoresist masks) replaced by other steps.

For instance, opening of the passivation 12 at the region or area dedicated to DCI processing can be based on different approaches.

For instance, both areas (DCI and EWS) can be created using a single mask landing on the finishing 14 in the area EWS and indenting the passivation 12 in the area DCI: in that way a dedicated mask for DCI opening/passivation indenting will be involved.

Also, both areas (DCI and EWS) can be created using again a single mask landing on the finishing 14 in the area EWS and indenting passivation in the area DCI. An additional mask could be involved in completing the passivation indenting in the area DCI in case indenting is not sufficient.

Alternatively, essentially as illustrated herein, two masks such as MLI and ML3 can be used to “open” the passivation layers in separated steps for the first region or area dedicated to EWS and in the second area dedicated to DCI.

FIGS. 2, 3 and 4 plus 6 are (partial) cross-sectional views of semiconductor products suited to be manufactured according with embodiments of the present description.

These figures are exemplary of the provision of a metal layer 10, comprising, e.g., a Cu Damascene top metallization of an (otherwise conventional) underlying semiconductor chip or die structure 106.

FIGS. 2 to 5 are exemplary of solutions obtainable via steps as discussed in the foregoing in connection with FIGS. 1A to 1G applied on a “Damascene” copper layer 10 formed (in manner known per se) on an insulating layer (e.g., silicon oxide) 200 patterned with trenches where a conductor is desired to be provided.

In such a process, a coating of copper is deposited on the insulator, and the copper in excess above the insulating layer is removed and left only in the trenches of the insulating layer to form a conductive pattern. A multilayer interconnect structure can be created as schematically indicated by reference 202.

FIGS. 2 to 5 illustrate the possibility of forming pad areas or regions (for EWS and DCI, respectively) on a unitary substrate 10—see FIGS. 2 and 3—or on two (or possibly more) substrates 10 not shorted together—see FIG. 4 (and FIG. 6).

All these figures show arrangements comprising an integrated circuit semiconductor chip structure 106 having formed thereon (e.g., above an insulating layer 200) a top or front metal layer 10 (e.g., copper 10).

The metal layer 10 has a passivation 12, 120 over a first, outer surface (facing upwards in the figures).

The first surface of the layer 10 comprises at least one first region EWS and at least one second region DCI.

The passivation is fully removed (including the layer 120) from the first region EWS and a contact layer 14 for electrical wafer sorting probes is formed over the first region EWS.

Conversely, the passivation is (only) at least partly removed from the second region DCI (that is, leaving in place the layer 120 or part of it or the layer 120 and part of 12) and electrically conductive material (see the via 102 in FIG. 6, for instance) is grown—electrolytically, for instance—directly on the metal layer 10 at the second region DCI, e.g., after removing the residual layer (e.g., the layer 120 or part of it or the layer 120 and part of 12).

The layer 10 has thus formed thereon (at its outer, upper surface): at least one first region (that is, the region labelled EWS) for landing EWS test probes; and at least one second region (that is, the region labelled DCI) suited for landing through-mold vias (TMVs) such as the electrically conductive via designated 102 in the semiconductor device 1000 illustrated in FIG. 6.

Such vias can be formed in an encapsulation 104 of LDS material and provide electrical connections for one or more semiconductor chips or dice 106.

Through-mold vias such as the via 102 (and electrically conductive lines or traces extending over the encapsulation 104 and connecting selected one of these vias) can be provided in a manner known per se to those of skill in the art as taught, for example, by: United States Patent Publications Nos. 2018/0342453 A1, 2019/0115287 A1, 2020/0203264 A1, 2020/0321274 A1, 2021/0050226 A1, 2021/0050299 A1, 2021/0183748 A1, or 2021/0305203 A1 (all of which are incorporated herein by reference and are exemplary of related techniques).

Processing as exemplified in FIG. 6, namely landing through-mold vias (TMVs) such as the electrically conductive via designated 102 at the second region DCI while removing the protective layer 120 therefrom (this may occur as a result of LDS laser “structuring” an LDS material encapsulation 104 as discussed in the commonly owned applications cited in the foregoing) may take place at a time and a location different from the time and the location where the steps illustrated in FIG. 1A to 1G are performed.

For instance, such processing can be performed by a sub-contractor that produces a final semiconductor device operating on an “intermediate” semiconductor product substantially corresponding to the assembly illustrated in FIG. 1G formed on an underlying semiconductor chip structure 106 (e.g., after a dicing step).

Such possible “splitting” of processing still relies on the general underlying concept of providing a die bonding pad structure comprising two zones or areas dedicated to Electrical Wafer Sorting (EWS) and metal growth as used in Direct Copper Interconnect (DCI)/Laser Direct Structuring (LDS), respectively.

As noted, FIGS. 3 and 4 are exemplary of the possibility of applying solutions as described herein to a solution (“passivated AlCap”, for instance) where an additional passivation 140 is provided at the periphery of the layer/finishing 14 at the (first) region EWS.

As noted: FIGS. 2 and 3 illustrate implementations where a single substrate 10 comprises two areas or regions EWS and DCI on a single metal (e.g., copper) pad; and FIGS. 4 and 6 illustrate implementations where these areas or regions—for landing EWS test probes and through mold vias, TMVs laser drilled or created with other etching methods—may be arranged as plural independent pads.

Consequently, EWS pads and/or DCI pads can be isolated and provided in combination of plural pads from a functional and co-integration point of view.

This possibility can be further appreciated from the plan view of a portion of a semiconductor device 1000 manufactured with embodiments of the present description as presented in FIG. 5.

Without prejudice to the underlying principles, the details and embodiments may vary, even significantly, with respect to what has been described by way of example only without departing from the extent of protection.

The claims are an integral part of the technical teaching provided herein in respect of the embodiments.

The extent of protection is determined by the annexed claims.

1. A method, comprising:
providing a semiconductor chip comprising a front metal layer over an insulator layer, wherein the front metal layer includes a first region and a second region, and wherein a surface passivation extends over the front metal layer;
fully removing the surface passivation from over the front metal layer at the first region to form a first passivation opening exposing an upper surface of the front metal layer at the first region, without fully removing the surface passivation from over the front metal layer at the second region;
forming a contact layer for electrical wafer sorting probes over the front metal layer in the passivation opening at the first region; and
partly removing the surface passivation from over the front metal layer at the second region to form a second passivation opening which does not expose the front metal layer at the second region, wherein the second region having the surface passivation partly removed defines, with the second passivation opening, a location for a growth region for growing electrically conductive material over the at least one second region of the front metal layer.

2. The method of claim 1, wherein the first region and the second region are provided at mutually insulated portions of the front metal layer.

3. The method of claim 1, wherein the first region and the second region are provided at mutually short-circuited portions of the front metal layer.

4. The method of claim 1, wherein the surface passivation comprises a protective layer for covering the upper surface of said front metal layer and:
fully removing the surface passivation comprises removing the protective layer from over the front metal layer at the first region; and
partly removing comprises leaving the protective layer on the upper surface of the front Damascene metal layer at the second region.

5. The method of claim 4, further comprising:
fully removing a portion of the protective layer from over the second region to form a third passivation opening; and
growing electrically conductive material in said third passivation opening on said front metal layer at the second region.

6. The method of claim 5, wherein the front metal layer comprises copper and wherein growing electrically conductive material comprises growing copper in said third passivation opening on said front metal layer.

7. The method of claim 4, further comprising:
forming a laser direct structuring insulating layer covering the surface passivation and covering the protective layer at the second region;
activating the laser direct structuring insulating layer with a via opening extending though the laser direct structuring insulating layer and through the protective layer at the second region to reach the upper surface of the front metal layer at the second region; and
growing electrically conductive material in said via opening to form an interconnect.

8. The method of claim 7, wherein the via opening is formed by laser beam ablation.

9. The method of claim 1, wherein the front metal layer comprises a Damascene metal layer.

10. A semiconductor product, comprising:
a semiconductor chip having a front metal layer with a surface passivation extending over the front metal layer, wherein the front metal layer includes a first region and a second region;
wherein full removal of the surface passivation over the front metal layer at the first region provides a first passivation opening which exposes the front metal layer at the first region;
a contact layer for contact with electrical wafer sorting probes, said contact layer located in the first passivation opening in contact with the front metal layer at the first region; and
wherein partial removal of the surface passivation over the front metal layer at the second region provides a second passivation opening which does not expose the front metal layer at the second region.

11. The semiconductor product of claim 10, wherein the surface passivation comprises a protective layer covering an upper surface of said front metal layer, wherein the protective layer is absent and does not cover said front metal layer at the first region, and wherein the protective layer is present and at least partly covers said front metal layer at the second region.

12. The semiconductor product of claim 11, further comprising:
a third passivation opening extending through a portion of the protective layer at the second; and
electrically conductive material in said third passivation opening on said front metal layer at the second region.

13. The semiconductor product of claim 12, wherein the front metal layer comprises copper and wherein the electrically conductive material comprises copper.

14. The semiconductor product of claim 11, further comprising:
a laser direct structuring insulating layer covering the surface passivation and covering the protective layer at the second region;
a via opening extending though the laser direct structuring insulating layer and through the protective layer at the second region to reach the upper surface of the front metal layer at the second region; and
electrically conductive material in said via opening to form an interconnect.

15. The semiconductor product of claim 10, wherein the front metal layer comprises a Damascene metal layer.

16. A device, comprising:
a semiconductor chip having a front metal layer with a surface passivation extending over the front metal layer, wherein the front metal layer includes a first region and a second region;
wherein the surface passivation includes a first full through opening over the front metal layer at the first region to provide a first passivation opening which exposes the front metal layer at the first region;
a contact layer for electrical wafer sorting probes located in the first passivation opening in contact with the front metal layer at the first region;
wherein the surface passivation includes a second partial opening over the front metal layer at the second region to provide a second passivation opening; and
electrically conductive material grown onto the front metal layer at the second region where said second partial opening in the surface passivation is located.

17. The device of claim 16, wherein surface passivation includes a protective layer at the upper surface of the front metal layer at the second region in the second passivation opening;
wherein a portion of the protective layer is partly removed at the second passivation opening where the protective layer is partly removed; and
wherein said electrically conductive material grown is present where the portion of the protective layer is partly removed.

18. The device of claim 17, further including an insulating layer covering the surface passivation and covering the protective layer at the second region, said insulating layer including a via opening extending through the insulating layer and the protective layer at the second region, and wherein said electrically conductive material is grown in said via opening.

19. The device of claim 16, wherein the front metal layer comprises a Damascene metal layer.
